(19) United States
(12) Patent Application Publication
(10) Pub. No.: US 2017/0012065 A1
(43) Pub. Date: Jan. 12, 2017

(54) ARRAY SUBSTRATE, A METHOD FOR MANUFACTURING THE SAME, AND DISPLAY DEVICE

(71) Applicants: BOE TECHNOLOGY GROUP CO., LTD., Beijing (CN); BEIJING BOE OPTOELECTRONICS TECHNOLOGY CO., LTD., Beijing (CN)

(72) Inventors: Zhilian XIAO, Beijing (CN); Haisheng ZHAO, Beijing (CN); Zhilong PENG, Beijing (CN); Xiaoguang PEI, Beijing (CN); Chong LIU, Beijing (CN)

(21) Appl. No.: 15/159,415

(22) Filed: May 19, 2016

(30) Foreign Application Priority Data
Jul. 10, 2015 (CN) 201510405436.3

(51) Int. Cl. H01L 27/12; H01L 21/311; H01L 29/786; H01L 29/66

(52) U.S. Cl. CPC H01L 27/1288; H01L 29/6675; H01L 21/31138; H01L 29/78672; H01L 27/1214; H01L 29/78696

(57) ABSTRACT

The present invention provides an array substrate, a method for manufacturing the same, and a display device including the same. In the manufacturing method of the present invention, photoresist is exposed and developed by using a mask to allow the first regions to retain photoresist with a first thickness and second regions to retain photoresist with a second thickness, wherein the first thickness is greater than the second thickness, and each of the first regions is at least partially connected with the second region, so that the contact area between the exposed photoresist and the substrate is large and the photoresist in the first regions is unlikely to peel off. The manufacturing method of the present invention is applicable to manufacturing various array substrates.

### FIELD OF THE INVENTION

The present invention relates to the field of display technology, and particularly relates to an array substrate, a method for manufacturing the same, and a display device including the array substrate.

### BACKGROUND OF THE INVENTION

A thin film transistor in an array substrate is a key device. The region where the thin film transistor is located is light-proof, so it is desired that the occupying area of the thin film transistor in the whole array substrate should be as small as possible, and corresponding active regions are designed to be decreased gradually.

The inventor found that the prior art at least had the following technical problems: as shown in FIGS. 1 and 2, the active region is formed by etching the semiconductor material layer 4, and the part covered by the photoresist 5 during etching is retained to form the active region; due to the fact that the active region has a small size, after the photoresist 5 on the semiconductor material layer 4 is exposed and developed, the contact area between the residual photoresist 5 and the substrate 1 is small, which results in that small photoresist 5 is extremely likely to peel off in the developing process, and after the photoresist is peeled off, the active region cracks when the active region is etched, then resulting in pixel fault. Of course, FIG. 1 further includes a mask 6, and FIGS. 1 and 2 further include gates 2, a gate insulation layer 3 and other conventional structures, which are not described in detail herein.

Moreover, in the prior art, there is originally a step of cleaning the substrate 1 before coating the photoresist on the semiconductor material layer 4, so as to remove contaminants on the substrate 1 (or the active region) to improve the quality of the thin film transistor. However, in the case that the photoresist 5 is coated after the substrate 1 is cleaned, the adhesivity of the photoresist 5 becomes worse and the photoresist 5 peels off more easily. Therefore, the step of cleaning the substrate 1 has been removed in the prior art.

### SUMMARY OF THE INVENTION

In view of the problem that the contact area between the exposed and developed photoresist on the existing semiconductor material layer and the substrate is small to cause the photoresist to peel off easily, the present invention provides an array substrate, a method for manufacturing the same, and a display device including the array substrate.

The technical solution employed for solving the technical problem of the present invention is as follows.

A manufacturing method of an array substrate comprises the following steps:

forming a semiconductor material layer on the substrate, wherein a part of regions form an active region of a semiconductor thin film transistor;

coating photoresist on the semiconductor material layer, the photoresist at least comprises a first region and a second region, wherein the first regions correspond to the active regions of the semiconductor thin film transistor;

exposing and developing the photoresist by using a mask to allow the first regions to retain photoresist with a first thickness and the second regions to retain photoresist with a second thickness, wherein the first thickness is greater than the second thickness, and each of the first regions is at least partially connected with the second region;

ashing the developed photoresist to remove the photoresist in the second regions and still retain at least part of the photoresist in the first regions;

etching the substrate subjected to the steps above to remove the exposed semiconductor material layer, in order to form the active regions of the thin film transistor.

The semiconductor material layer is preferably a polycrystalline silicon layer.

The photoresist is exposed by using a mask, preferably, the mask is a half tone mask. That is, the photoresist is exposed by using a semi-transparent exposure method.

A step of cleaning the substrate is preferably comprised between the step of forming the semiconductor material layer on the substrate and the step of coating the photoresist on the semiconductor material layer.

Preferably, a third region without photoresist is further formed when the photoresist is exposed and developed by using the mask.

Preferably, each of the first regions is surrounded by the second region, and the width of the second region is at least 8 μm to 7 μm in any direction outside of the first region.

Preferably, all of the second regions on the substrate are connected into a whole.

Preferable, the first thickness is 8 μm to 12 μm.

Preferable, the second thickness is 0.2 μm to 0.6 μm.

The term “semi-transparent exposure” refers to an incomplete exposure mode in which a part of the photoresist is exposed by using the mask. In an embodiment, the first regions of the photoresist correspond to the light-proof part of the mask, the second regions correspond to the semi-transparent part of the mask, and optionally, the third region corresponds to the completely transparent part of the mask.

The term ashing technology is a built-in function of the existing dry etching equipment, and mainly used for removing photoresist in a current TFT-LCD production line. It has the same steps as dry etching of Si, but only differs from the later in aspects of Power, Gases and Time.

The ashing technology has similar function to EUV which employs O₃. The etching technology uses O₂, in which plasma bombardment is carried out in a chamber to enhance active reaction and remove organics on the surface of the substrate, and because CHO (carbon, hydrogen and oxygen) exists in the photoresist, in a manufacture procedure process, the ashing technology is mainly applied to the process of removing the photoresist. For example, a-Si Etch mainly adopts Cl₂ and SF₆ to react with the photoresist likewise, with the existing etching rate of 2000 A/min, while the ashing technology mainly adopts O₂, with the etching rate of 8000 A/min. Therefore, the ashing approach is mainly used for etching the photoresist (PR) in mass production.

In the present invention, the first regions and the second regions are formed after the photoresist is exposed and developed by using the mask, and preferably, each of the first regions is surrounded by the second region. The photoresist in the second regions is selectively removed by using the ashing technology and controlling power, time and the like, while the first regions still retain at least part of the photoresist. Herein, the term “selectively” means having certain selectivity on the thickness of the photoresist by controlling power and time. Of course, the width changes along with the thickness, but the change of the thickness is dominant, and time is increased or decreased as needed.

The present invention further provides an array substrate which is manufactured by the method above.

The present invention further provides a display device, including the array substrate above.

In the manufacturing method of the array substrate of the present invention, photoresist is exposed and developed by using a mask to allow a first region to retain photoresist with a first thickness and a second region to retain photoresist with a second thickness, wherein the first thickness is greater than the second thickness, each of the first regions is at least partially connected with the second region, so that the contact area between the exposed photoresist and the substrate is large and the photoresist in the first regions is unlikely to peel off The manufacturing method of the array substrate of the present invention is applicable to manufacturing various array substrates.

### BRIEF DESCRIPTION OF THE DRAWINGS

FIG. 1 is a schematic view of a manufacturing method of the existing array substrate;

FIG. 2 is a schematic view of the existing array substrate after exposure and development;

FIG. 3 is a schematic view of a manufacturing method of the array substrate in embodiment 2 of the present invention;

FIG. 4 is a schematic view of the array substrate in embodiment 2 of the present invention after exposure and development; and

FIG. 5 is a top schematic view of the array substrate in embodiment 2 of the present invention after exposure and development.

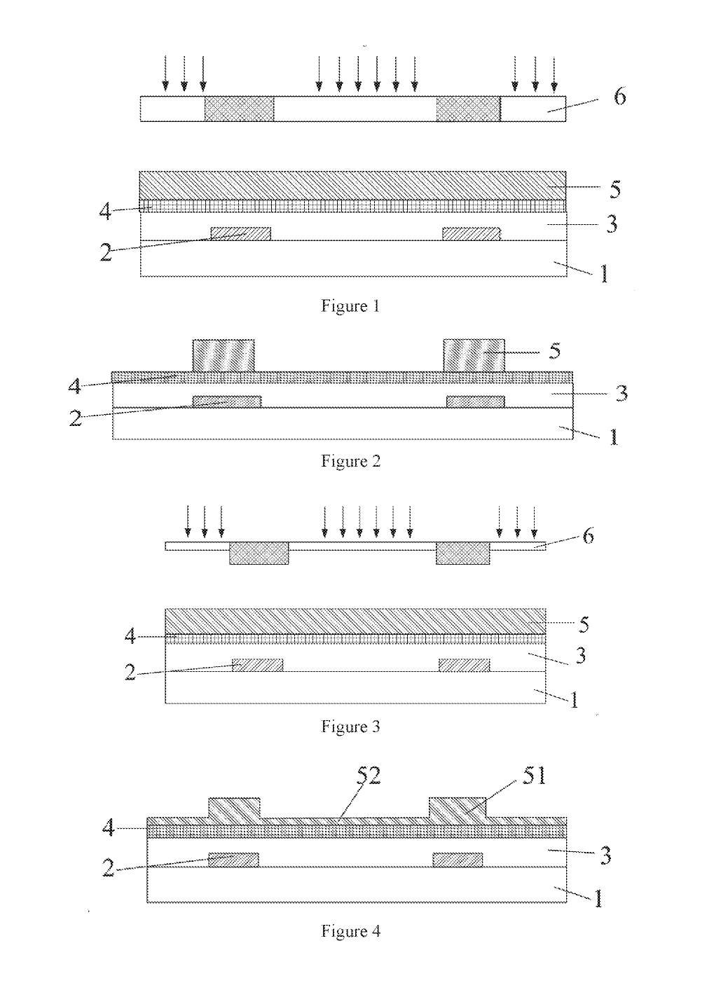

Reference signs: 1. substrate; 2. gate; 3. gate insulation layer; 4. semiconductor material layer; 5. photoresist; 51. first region; 52, second region; 6. mask.

### DESCRIPTION OF THE PREFERRED EMBODIMENT

In order to make a person skilled in the art better understand the technical solution of the present invention, the present invention will be further described in detail in conjunction with the accompanying drawings and specific embodiments.

### Embodiment 1

The embodiment provides a manufacturing method of an array substrate, comprising the following steps:

forming a semiconductor material layer on the substrate, wherein a part of regions form an active region of a semiconductor thin film transistor;

coating photoresist on the semiconductor material layer, the photoresist at least comprises a first region and a second region, wherein the first regions correspond to the active region of the semiconductor thin film transistor;

exposing and developing the photoresist by using a mask to allow the first regions to retain photoresist with a first thickness and the second regions to retain photoresist with a second thickness, wherein the first thickness is greater than the second thickness, and each of the first regions is at least partially connected with the second region;

ashing the developed photoresist to remove the photoresist in the second regions and still retain at least part of the photoresist in the first regions;

etching the substrate subjected to the steps above to remove the exposed semiconductor material layer, in order to form the active region of the thin film transistor.

In the manufacturing method of the array substrate of the embodiment, the photoresist is exposed and developed by using a mask to allow the first regions to retain photoresist with a first thickness and the second regions to retain photoresist with a second thickness, wherein the first thickness is greater than the second thickness, each of the first regions is at least partially connected with the second region, so that the exposed photoresist corresponding to the active region is further connected with other photoresist (photoresist in the second regions). Therefore, the contact area between the exposed photoresist and the substrate is large, and the photoresist in the first regions will not peel off in subsequent steps. The manufacturing method of the array substrate of the embodiment is applicable to manufacturing various array substrates

### Embodiment 2

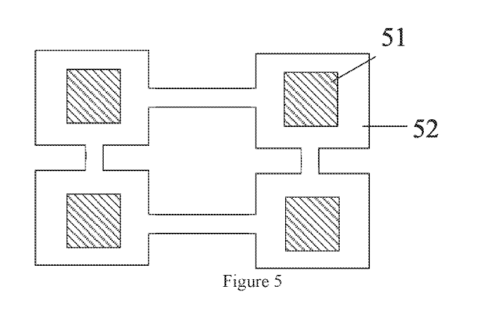

As shown in FIGS. 3-5, this embodiment provides a manufacturing method of an array substrate, comprising the following steps:

S01, a semiconductor material layer 4 is formed on the substrate 1, wherein a part of regions form active regions of a semiconductor thin film transistor.

The semiconductor material layer 4 is preferably a polycrystalline silicon layer.

S02, photoresist 5 is coated on a semiconductor material layer 4, the photoresist 5 at least comprises a first region 51 and a second region 52, wherein the first regions 51 correspond to active regions of the semiconductor thin film transistor.

S03, the photoresist 5 is exposed and developed by using a mask 6 to allow the first regions 51 to retain photoresist with a first thickness and the second regions 52 to retain photoresist with a second thickness, wherein the first thickness is greater than the second thickness, the first regions 51 are regions corresponding to the active regions of the thin film transistor, and each of the first regions 51 is at least partially connected with the second region 52.

The photoresist 5 is exposed by using a mask 6, preferably, the mask 6 is a half tone mask. That is, when the photoresist 5 is exposed by using the mask 6, preferably, semi-transparent exposure is carried out on the photoresist 5. The first regions 51 of the photoresist 5 correspond to the light-proof part of the mask, and the second regions 52 correspond to the semi-transparent part of the mask. in the prior art, during a 4Mask process, that is, a-Si and SD are further subjected to mask exposure in one step, semi-transparent exposure is adopted for lamination at a channel, the residue semi-transparent photoresist and SD after development are etched by DE, the Mask is called HT Mask, and such a structure is mostly used in a low-end product with a low resolution.

Further preferably, a step of cleaning the substrate 1 is further comprised between step S01 and step S02.

In the prior art, there is originally a step of cleaning the substrate 1 before coating the photoresist on the semiconductor material layer 4. However, in the case that the photoresist 5 is coated after the substrate 1 is cleaned, the adhesivity of the photoresist 5 becomes worse and the photoresist 5 peels off more easily. Therefore, the step of cleaning the substrate 1 has been abandoned in the prior art. However, the semi-transparent exposure mode is adopted in the present invention to increase the contact area between the photoresist 5 after development and the substrate 1, so peeling off will not be caused even if the step of cleaning the substrate 1 is comprised.

Preferably, a third region without photoresist is further formed when the photoresist 5 is exposed and developed by using the mask 6. The third region corresponds to a region not covered by the mask or to a completely transparent part of the mask.

Preferably, each of the first regions 51 is surrounded by the second region 52, and the size of the first region is within the range of 3 μm to 15 μm, and the width of the second region 52 is at least 3 μm to 7 μm in any direction outside of the first region 51.

Preferably, all of the second regions 52 on the substrate 1 are connected into a whole.

That is to say, in order to reduce the ashing amount of the photoresist 5, independent semiconductor material layers 4 can be connected, and the above semi-transparent mode is adopted for the connection parts, as long as the first regions 51 are surrounded by a thin layer of photoresist 5 in the second regions 52, the contact area between the photoresist 5 and the substrate 1 is increased to ensure the photoresist 5 does not peel off. As shown in FIG. 5, there is a top schematic view of an array substrate after exposure and development. FIG. 5 shows a top schematic view of area sizes of the first regions 51 and the second regions 52 after the photoresist 5 in four adjacent active regions are exposed and developed.

Preferably, the first thickness is 8 μm to 12 μm.

Preferably, the second thickness is 0.2 μm to 0.6 μm.

S04, the developed photoresist is ashed to remove the photoresist of the second regions 52 and still retain at least part of the photoresist 5 in the first regions 51.

S05, the substrate 1 subjected to the steps above is etched to remove the exposed semiconductor material layer 4, in order to form the active region of the thin film transistor.

That is to say, the exposure amount of the second regions 52 is reduced by semi-transparent exposure in the embodiment to increase the contact area between the photoresist 5 after development and the substrate 1, thus solving the problem that the active region cracks when being etched because the contact area between the photoresist 5 and the substrate 1 is small to result in peeling off of the photoresist 5 during development. In order not to affect the subsequent etching process, an ashing step is added to remove thinner photoresist in the second regions 52 through ashing.

Specifically, in the process of ashing, a matrix with the photoresist enters a reaction chamber, O₂ is introduced to react with the photoresist by setting power and time, the photoresist in the second regions is selectively removed, and the first regions still retain at least part of the photoresist.

Of course, during manufacturing of the array substrate, the method further comprises the step of forming gates 2, a gate insulation layer 3, sources, drains and other known structures, which is not described in detail herein.

### Embodiment 3

The embodiment provides an array substrate, which is manufactured by using the method in embodiment 2.

Obviously, various changes can be made to the specific implementation modes of the above embodiments. For example, the specific areas and forms of the first regions and the second regions can be designed as needed, or different masks can be replaced according to different requirements to realize a certain value of the first thickness and the second thickness.

### Embodiment 4

The embodiment provides a display device, including the array substrate manufactured by any one of the aforementioned methods. The display device may be a liquid crystal display panel, electronic paper, an OLED panel, a mobile phone, a tablet computer, a TV, a display, a notebook computer, a digital photo frame, a navigator or any product or component with a display function.

It may be understood that the aforementioned embodiments are merely exemplary embodiments used for illustrating the principle of the present invention, and the present invention is not limited thereto. For a person skilled in the art, various variations and improvements may be made without departing from the spirit and essence of the present invention, and those variations and improvements are also encompassed within the protection scope of the present invention.

1. A manufacturing method of an array substrate, comprising the following steps:
forming a semiconductor material layer on the substrate, wherein a part of regions form an active region of a semiconductor thin film transistor;
coating photoresist on the semiconductor material layer, the photoresist at least comprises a first region and a second region, wherein the first regions correspond to the active regions of the semiconductor thin film transistor;
exposing and developing the photoresist by using a mask to allow the first regions to retain photoresist with a first thickness and the second regions to retain photoresist with a second thickness, wherein the first thickness is greater than the second thickness, and each of the first regions is at least partially connected with the second region;
ashing the developed photoresist to remove the photoresist in the second regions and still retain at least part of the photoresist in the first regions;
etching the substrate subjected to the steps above to remove the exposed semiconductor material layer, in order to form the active regions of the thin film transistor.

2. The manufacturing method of the array substrate according to claim 1, wherein the semiconductor material layer is a polycrystalline silicon layer.

3. The manufacturing method of the array substrate according to claim 1, wherein the exposure mode is semi-transparent exposure.

4. The manufacturing method of the array substrate according to claim 1, wherein a step of cleaning the substrate is further comprised between the step of forming the semiconductor material layer on the substrate and the step of coating the photoresist on the semiconductor material layer.

5. The manufacturing method of the array substrate according to claim 1, wherein a third region without photoresist is further formed when the photoresist is exposed and developed by using the mask.

6. The manufacturing method of the array substrate according to claim 1, wherein each of the first regions is surrounded by the second region, and the width of the first region is within the range of 3 μm to 15 μm, and the width of the second region is at least 3 μm to 7 μm in any direction outside of the first region.

7. The manufacturing method of the array substrate according to claim 1, wherein all of the second regions on the substrate are connected into a whole.

8. A manufacturing method of the array substrate according to claim 1, wherein the first thickness is 8 μm to 12 μm.

9. The manufacturing method of the array substrate according to claim 1, wherein the second thickness is 0.2 μm to 0.6 μm.

10. An array substrate, manufactured by using the method according to claim 1, wherein the size of the active region is within the range from 3 μm to 15 μm.

11. An array substrate, manufactured by using the method according to claim 2, wherein the size of the active region is within the range from 3 μm to 15 μm.

12. An array substrate, manufactured by using the method according to claim 3, wherein the size of the active region is within the range from 3 μm to 15 μm.

13. An array substrate, manufactured by using the method according to claim 4, wherein the size of the active region is within the range from 3 μm to 15 μm.

14. An array substrate, manufactured by using the method according to claim 5, wherein the size of the active region is within the range from 3 μm to 15 μm.

15. An array substrate, manufactured by using the method according to claim 6, wherein the size of the active region is within the range from 3 μm to 15 μm.

16. An array substrate, manufactured by using the method according to claim 7, wherein the size of the active region is within the range from 3 μm to 15 μm.

17. An array substrate, manufactured by using the method according to claim 8, wherein the size of the active region is within the range from 3 μm to 15 μm.

18. An array substrate, manufactured by using the method according to claim 9, wherein the size of the active region is within the range from 3 μm to 15 μm.

19. A display device, comprising the array substrate according to claim 10.
